(19) United States
(12) Patent Application Publication
(10) Pub. No.: US 2010/0201735 A1
(43) Pub. Date: Aug. 12, 2010

(54) BONDING METHOD OF SILICON BASE MEMBERS, DROPLET EJECTION HEAD, DROPLET EJECTION APPARATUS, AND ELECTRONIC DEVICE

(75) Inventors: Mitsuru Sato, Nagano (JP); Yoshiaki Mori, Nagano (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 12/665,284

(22) PCT Filed: Jun. 16, 2008
(86) PCT No.: PCT/JP2008/060988

§ 371 Date: Dec. 17, 2009

(30) Foreign Application Priority Data
Jun. 18, 2007 (JP) 2007-160798

(51) Int. Cl. B41J 2/015; H01L 21/30

(52) U.S. Cl. 347/20; 438/455; 257/E21.211

(57) ABSTRACT

A bonding method of silicon base members is provided. The bonding method of silicon base members comprises: applying an energy to a surface of a first silicon base member having Si—H bonds on the surface to selectively cut the Si—H bonds so that dangling bonds of the silicon (Si) is exposed on the surface of the first silicon base member; and bonding the surface of the first silicon base member, on which the dangling bonds of the silicon has been exposed, and a surface of a second silicon base member on which dangling bonds of silicon are exposed so that the surface of the first silicon base member and the surface of the second silicon base member are bonded together through their dangling bonds.

### CROSS-REFERENCE TO RELATED APPLICATION

This application claims priorities to Japanese Patent Application No. 2007-160798 filed on Jun. 18, 2007 which is hereby expressly incorporated by reference herein in its entirety.

### BACKGROUND

1. Technical Field

The present invention relates to a bonding method of silicon base members, a droplet ejection head, a droplet ejection apparatus, and an electronic device, and more specifically relates to a bonding method of silicon base members, a droplet ejection head provide with a bonded body manufactured by the bonding method, a droplet ejection apparatus provided with the droplet ejection head, and an electronic device provided with the bonded body.

2. Related Art

Conventionally, as a method of bonding two silicon substrates (silicon base members) to each other, there is known a wafer direct bonding method which is a method of directly bonding two wafers (silicon substrates) to each other.

Generally, the wafer direct bonding method is performed as follows. First, two silicon substrates are washed. Then, they are subjected to a surface treatment to thereby bond a large number of hydroxyl groups on the surfaces of the two silicon substrates. Thereafter, the surface-treated surfaces of the two silicon substrates are overlapped to each other. Next, the overlapped two silicon substrates are subjected to a heating treatment at a temperature of about 1000° C. to bond the two silicon substrates together.

In this way, when the wafer direct bonding method is performed by overlapping the surfaces of the two silicon substrates to which the hydroxyl groups have been bonded, and then subjecting the overlapped two silicon substrates to the heating treatment, Si—O—Si bonds are produced by reacting Si—OH bonds to each other which exist on the surface of each of the two silicon substrates. That is, the Si—O—Si bonds are produced by dehydration between the Si—OH bonds.

The Si—O—Si bonds make it possible to firmly bond the two silicon substrates. Since no adhesive is used in this wafer direct bonding method, there is no problem that the adhesive gets out of between the two silicon substrates. The wafer direct bonding method makes it possible to accurately bond the two silicon substrates together with an easy process. Therefore, the wafer direct bonding method is expected to be used in various applications such as MEMS (Micro Electro Mechanical Systems) assembling, a semiconductor elements, various kinds of packages, and the like.

However, a conventional wafer direct bonding method requires a heating treatment at a temperature of about 1000° C. Therefore, in a case where an electronic circuit and a movable structural body are formed in a silicon substrate, there is a problem in that the electronic circuit and the movable structural body are damaged due to the heat.

In such a case, at least one of the surfaces of the two silicon substrates is subjected to a hydrophilic treatment with oxygen plasma obtained by using a plasma generation apparatus. Thereafter, the hydrophilic-treated surfaces are overlapped to each other, and then the overlapped silicon substrates are subjected to a heating treatment at a temperature in the range of 200 to 450° C. One example of such a bonding method is disclosed in a patent document.

However, the above bonding method is performed by bonding the two silicon substrates to each other through the Si—O—Si bonds. Therefore, sufficient bonding strength cannot be obtained. Additionally, chemical bonds exist nonuniformly in (on) a bonding surface between the two silicon substrates, thereby lowering mechanical characteristics, electrical characteristics, and chemical characteristics in (on) the bonding surface.

Therefore, in a case where a semiconductor device is manufactured by bonding a p-type silicon substrate and an n-type silicon substrate together, contact resistance due to the Si—O—Si bonds is caused in the bonding surface between the two silicon substrates. As a result, there is a fear that characteristics of the semiconductor device are lowered.

Generally, a surface of a silicon substrate is smoothed by a mechanical polishing or a chemical polishing. However, such a polished surface cannot have sufficient smoothness property. Therefore, it is difficult to bond the silicon substrates, which have been subjected to a polishing treatment, together with high strength and high accuracy without gaps therebetween.

The patent document is JP A-5-82404 as an example of related art.

### SUMMARY

Accordingly, it is an object of the present invention to provide a bonding method of silicon base members being capable of firmly and accurately bonding the silicon base members together without subjecting them to a heating treatment at a high temperature.

Further, it is another object of the present invention to provide a droplet ejection head having reliability and including a bonded body manufactured by using such a bonding method, and a droplet ejection apparatus provided with such a droplet ejection head.

Furthermore, it is other object of the present invention to provide an electronic device including the bonded body manufactured by using such a bonding method.

These objects are achieved by the present invention described below.

In a first aspect of the present invention, there is provided a bonding method. The bonding method comprises: applying an energy to a surface of a first silicon base member having Si—H bonds on the surface to selectively cut the Si—H bonds so that dangling bonds of the silicon (Si) is exposed on the surface of the first silicon base member; and bonding the surface of the first silicon base member, on which the dangling bonds of the silicon has been exposed, and a surface of a second silicon base member on which dangling bonds of silicon are exposed so that the surface of the first silicon base member and the surface of the second silicon base member are bonded together through their dangling bonds.

According to such a bonding method of the present invention, it is possible to firmly and accurately bonding silicon base members (first and second silicon base members) together without subjecting them to a heating treatment at a high temperature.

In the above bonding method, it is preferred that the energy includes a laser light, and the applying the energy to the surface of the first silicon base member is performed by irradiating the laser light.

According to such a bonding method of the present invention, it is possible to selectively and efficiently cut the Si—H bonds while reliably preventing the first silicon base member from being altered and deteriorated.

In the above bonding method, it is also preferred that the laser light includes a pulse laser.

According to such a bonding method of the present invention, heat is difficult to be accumulated in a part (surface) of the first silicon base member, in which the laser light has been irradiated, over time. Therefore, it is possible to reliably prevent the first silicon base member from being altered and deteriorated due to the accumulated heat. As a result, it is possible to prevent heat accumulated inside the first silicon base member from having an adverse affect on the first silicon base member.

In the above bonding method, it is also preferred that the first silicon base member has a part in which the laser light has been irradiated, and conditions of irradiating the laser light to the surface of the first silicon base member are adjusted so that a temperature of the part is in the range of room temperature to 600° C.

According to such a bonding method of the present invention, it is possible to selectively cut only the Si—H bonds at the surface of the first silicon base member in which the laser light has been irradiated without cutting most of the Si—Si bonds.

In the above bonding method, it is also preferred that the applying the energy to surface of the first silicon base member is performed with heating the first silicon base member.

According to such a bonding method of the present invention, it is possible to apply the energy to the surface of the first silicon base member with ease without use of expensive equipment.

In the above bonding method, it is also preferred that a temperature of heating the first silicon base member is in the range of 200 to 600° C.

According to such a bonding method of the present invention, it is possible to selectively cut the Si—H bonds.

In the above bonding method, it is also preferred that the first silicon base member is provided by: providing a base member constituted of a silicon material, the base member having a surface; and subjecting the surface of the base member to an etching treatment using a hydrofluoric acid-containing liquid to provide the first silicon base member.

According to such a bonding method of the present invention, such a hydrofluoric acid-containing liquid has very high etching selectivity of oxide silicon with respect to silicon. Therefore, if the hydrofluoric acid-containing liquid is used as an etching liquid, it is possible to selectively remove oxide silicon formed on a base material while preventing the base material (constituent material) of the base member from being deteriorated. As a result, it is possible to expose dangling bonds of silicon on the surface of the base member (first silicon base member).

In the above bonding method, it is also preferred that the base member constituted of the silicon material is formed by a CVD method using a silane-based gas as a raw gas.

According to such a bonding method of the present invention, it is possible to efficiently form a first silicon base member constituted of hydrogenated amorphous silicon.

In the above bonding method, it is also preferred that the applying the energy to the surface of the first silicon base member and the bonding the surface of the first silicon base member and the surface of the second silicon base member are performed in an inert gas atmosphere or a reduced-pressure atmosphere.

According to such a bonding method of the present invention, it is possible to reliably prevent the surface of the first silicon base member and the surface of the second silicon base member from being polluted and oxidized by adhesion of oxygen and moisture contained in an atmosphere. As a result, it is possible to prevent the dangling bonds exposed on the surfaces of the first and second silicon base members from being undesirably end-capped by oxygen and hydroxyl groups.

In the above bonding method, it is also preferred that the bonding the surface of the first silicon base member and the surface of the second silicon base member is performed with heating the first silicon base member and the second silicon base member.

According to such a bonding method of the present invention, it is possible to increase the bonding strength of a bonded body with reduced of bonding time.

In the above bonding method, it is also preferred that a temperature of heating the first silicon base member and the second silicon base member is in the range of 40 to 200° C.

According to such a bonding method of the present invention, it is possible to prevent the first silicon base member and the second silicon base member from being altered and deteriorated due to the heat. In addition, it is possible to increase the bonding strength of the bonded body with reduced of bonding time.

In the above bonding method, it is also preferred that the bonding the surface of the first silicon base member and the surface of the second silicon base member is performed with pressing the first silicon base member and the second silicon base member in a direction of approaching them to each other.

According to such a bonding method of the present invention, it is possible to increase the bonding strength of the bonded body.

In the above bonding method, it is also preferred that a pressure of pressing the first silicon base member and the second silicon base member is in the range of 1 to 1000 MPa.

According to such a bonding method of the present invention, it is possible to reliably increase the bonding strength of the bonded body while preventing the first and second silicon base members from being damaged.

In the above bonding method, it is also preferred that the second silicon base member having the surface on which the dangling bonds of the silicon are exposed is provided by: providing a base member constituted of a silicon material, the base member having a surface; subjecting the surface of the base member to an etching treatment using a hydrofluoric acid-containing liquid to form Si—H bonds on the surface of the base member; and applying an energy to the etching-treated surface of the base member to selectively cut the Si—H bonds so that the dangling bonds of the silicon are exposed on the surface of the base member corresponding to the second silicon base member.

According to such a bonding method of the present invention, it is possible to obtain a bonded body regardless of crystal structures and compositions of the first and second silicon base members.

In a second aspect of the present invention, there is provided a droplet ejection head provided with a bonded body manufactured by bonding two silicon base members together. The bonded body is manufactured by the bonding method of the silicon base members described above.

Such a droplet ejection head can have high reliability.

In a third aspect of the present invention, there is provided a droplet ejection apparatus provided with the droplet ejection head described above.

Such a droplet ejection apparatus can have high reliability.

In a fourth aspect of the present invention, there is provided an electronic device provided with a bonded body manufactured by bonding two silicon base members together. The bonded body is manufactured by the bonding method of the silicon base members described above.

Such an electronic device can have high reliability.

### BRIEF DESCRIPTION OF THE DRAWINGS

FIGS. 1A to 1D are vertical sectional views for explaining an embodiment of a bonding method of silicon base members according to the present invention.

FIGS. 2E to 2G are vertical sectional views for explaining an embodiment of a bonding method of silicon base members according to the present invention.

FIG. 3 is a vertical sectional view showing a diode produced by using the bonding method of the silicon base members according to the present invention.

FIG. 4 is an exploded perspective view showing a droplet ejection head produced by using the bonding method of the silicon base members according to the present invention, wherein the droplet ejection head is configured as an ink jet type recording head.

FIG. 5 is a sectional view of the ink jet type recording head shown in FIG. 4.

FIG. 6 is a schematic view showing one embodiment of an ink jet printer provided with the ink jet type recording head shown in FIG. 4.

FIG. 7 is a vertical sectional view showing an electronic device produced by using the bonding method of the silicon base members according to the present invention.

### DESCRIPTION OF EXEMPLARY EMBODIMENTS

Hereinbelow, a bonding method of silicon base members, a droplet ejection head, a droplet ejection apparatus, and an electronic device according to the present invention will be described in detail with reference to preferred embodiments shown in the accompanying drawings.

Bonding Method of Silicon Base Members

First, a description will be made on a bonding method of silicon base members according to the present invention.

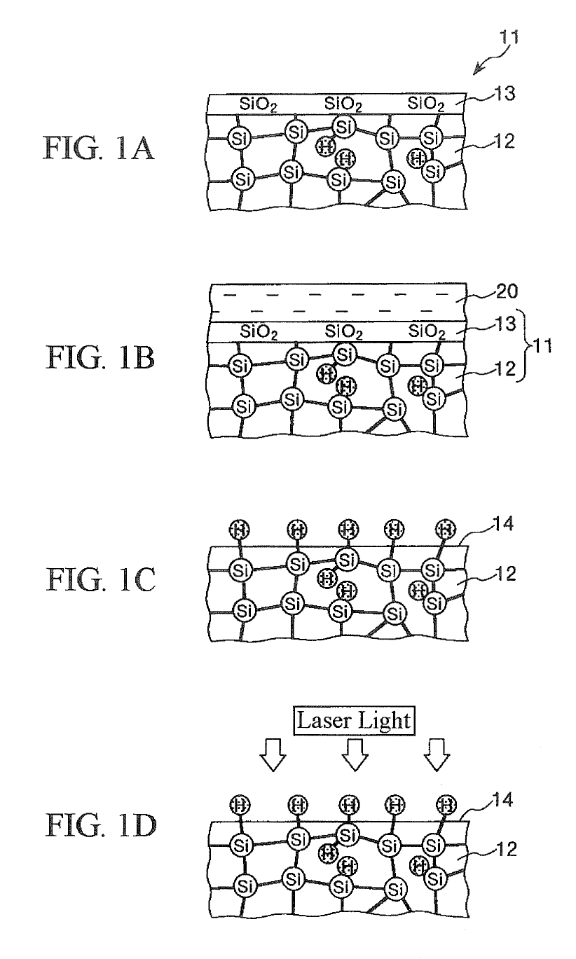

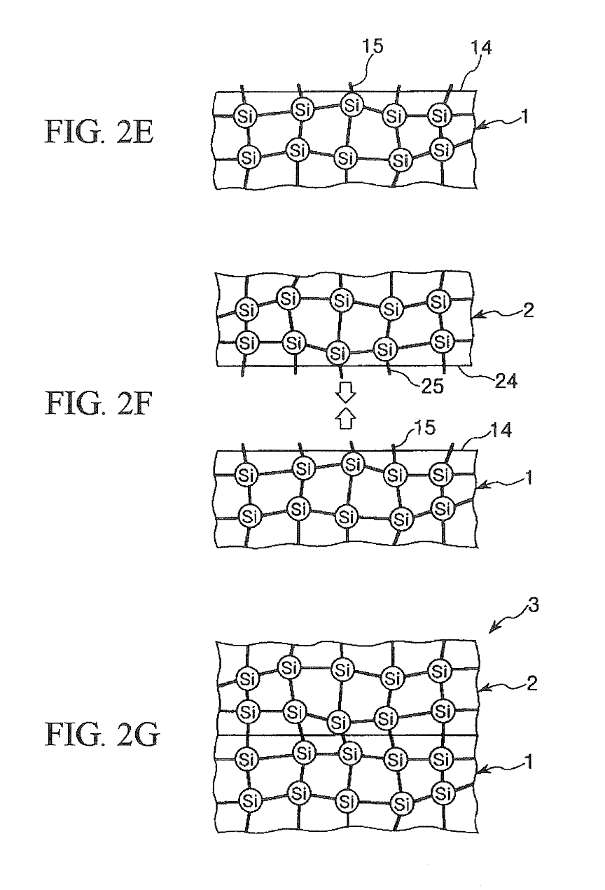

FIGS. 1A to 1D and 2E to 2G are vertical sectional views for explaining an embodiment of a bonding method of silicon base members according to the present invention. In the following description, the upper side in each of FIGS. 1A to 1D, and 2E to 2G will be referred to as “upper” and the lower side thereof will be referred to as “lower” for convenience of explanation.

The bonding method of the silicon base members according to the present invention is a method of directly bonding surfaces of two silicon base members (a first silicon base member 1 and a second silicon base member 2) together. Such a bonding method of the silicon base members includes the following two steps.

[1] A first step is an activation step of providing the first silicon base member 1 having Si—H bonds on a surface 14 thereof, and exposing dangling bonds 15 of silicon on the surface 14 thereof to activate the surface 14 thereof (first step).

[2] A second step is a bonding step of providing the second silicon base member 2 that dangling bonds 25 of silicon are exposed on a surface 24 thereof, and then bonding the surface 14 of the first silicon base member 1 and the surface 24 of the second silicon base member 2 to thereby bond them together (second step). Hereinafter, a description will be made on each step one after another.

[1] Activation Step (First Step)

In this embodiment, the first step includes the following three steps.

[1-1] A providing step is a step of providing a base member 11 constituted of silicon. [1-2] An etching step is a step of subjecting a surface of the bas member 11 to an etching treatment using a hydrofluoric acid-containing liquid 20.

[1-3] An activating step is a step of applying energy to the surface-treated surface of the base member 11 to expose dangling bonds 15 of silicon on the surface 14 of the first silicon base member 1 (base material 12), so that the surface 14 is activated. Hereinafter, a description will be made on each step one after another.

[1-1] Examples of a constituent material of the base member 11 shown in FIG. 1A which is provided in this step include: amorphous silicon; crystalline silicon such as monocrystalline silicon and polycrystalline silicon; and the like.

Amorphous silicon can be produced by using a vapor deposition method, a sputter method, various kinds of CVD methods such as a plasma CVD method and a heat CVD method, and the like.

It is preferred that hydrogenated amorphous silicon produced by the CVD method using a silane-based gas such as silane (SiH₄), disilane (Si₂H₆) and the like as a raw gas is used as the constituent material of the base member 11. Hydrogenated amorphous silicon produced by such a method is a material in which silicon atoms are not regularly arranged as a crystal structure but randomly arranged. The CVD method using silane makes it possible to efficiently produce a base member 11 (first silicon base member 1) constituted of hydrogenated amorphous silicon.

If the CVD method is performed by using a mask and the like, it is possible to selectively form a film (base member 11) constituted of hydrogenated amorphous silicon on only a predetermined region of a substrate. This makes it possible obtain an advantage that the base member 11 can be formed in a predetermined shape.

After the film constituted of hydrogenated amorphous silicon is formed on a whole of the substrate having a large surface area, the film may be subjected to a patterning process in combination of a photolithographic technique and an etching technique. The use of such a patterning process also makes it possible to form the base material 11 having a predetermined shape with ease.

A content of hydrogen contained in hydrogenated amorphous silicon is preferably in the range of about 0.5 to 20 atom %, and more preferably in the range of about 1 to 15 atom %. If the content of hydrogen contained in hydrogenated amorphous silicon falls within the above-noted range, it is possible to prevent mechanical characteristics of the base member 11 from being lowered.

If the content of hydrogen contained in hydrogenated amorphous silicon exceeds the upper limit value noted above, hydrogenated amorphous silicon is embrittled. As a result, there is a fear that mechanical characteristics thereof are lowered. Additionally, the content of hydrogen contained in hydrogenated amorphous silicon is too large. Therefore, it is difficult for such hydrogenated amorphous silicon to set conditions of producing a film by using a present film formation technology. As a result, there is a possibility that mass productivity of the film is lowered.

In the meantime, in a case where hydrogenated amorphous silicon is formed by the plasma CVD method, the content of hydrogen contained in hydrogenated amorphous silicon can be controlled by appropriately setting various kinds of parameters. Examples of the various kinds of the parameters include a composition of the raw gas, a flow rate thereof, an output of plasma, a pressure inside a chamber in a plasma CVD apparatus, a temperature of the film formation, and the like.

On the other hand, the crystalline silicon is a crystalline material having a diamond-type crystal structure.

In the monocrystalline silicon of the crystalline silicon, silicon atoms are regularly arranged in the entire material. In contrast, the polycrystalline silicon is a material which is formed by gathering particles of monocrystalline silicon having a different plane direction.

Further, a p-type dopant and an n-type dopant, if necessary, may be added to the base member 11. This makes it possible to control electrical characteristics of the base member 11.

Generally, in the base member 11, an oxide film 13 constituted of oxide silicon is formed on a surface of the base material 12 constituted of the silicon material as shown in FIG. 1A. The oxide film 13 is formed naturally on the surface of the base material 12 due to oxygen and moisture contained in an atmosphere.

[1-2] Next, the provided base member 11 is subjected to an etching treatment using a hydrofluoric acid-containing liquid 20. The hydrofluoric acid-containing liquid 20 is a hydrofluoric acid-based etching liquid. Examples of such a hydrofluoric acid-based etching liquid include a hydrofluoric acid (HF) solution, a buffered hydrofluoric acid (mixture of hydrofluoric acid and ammonium fluoride (NH₄F)), and the like. Such a hydrofluoric acid-containing liquid 20 has very high etching selectivity of oxide silicon with respect to silicon.

Therefore, if the hydrofluoric acid-containing liquid 20 is used as an etching liquid, it is possible to selectively remove the oxide silicon formed on the base member 11 while preventing the base material (constituent material) 12 of the base member 11 from being deteriorated.

As described above, the oxide film 13 constituted of oxide silicon is formed on the base material 12 due to oxygen and moisture contained in the atmosphere. However, only the oxide film 13 can be selectively removed from the base member 11 (base material 12) by the etching treatment using the hydrofluoric acid-containing liquid 20.

By subjecting the oxide film 13 to the etching treatment using the hydrofluoric acid-containing liquid 20, it is possible to improve smoothness property of the surface of the base member 11 (base material 12). This makes it possible to improve adhesion of the surface 14 of the first silicon base member 1 to be bonded when the two silicon base members 1 and 2 are bonded to each other in the step described later. Therefore, it is possible to bond the two silicon base members 1 and 2 together with high bonding strength and high accuracy.

If the oxide film 13 is removed from the base material 12, the dangling bonds 15 of silicon are exposed on the surface 14 of the base material 12. However, hydrogen ions contained in the hydrofluoric acid-containing liquid 20 are quickly bonded to the dangling bonds 15 of silicon, thereby end-capping the dangling bonds 15. In this way, the first silicon base member 1 having the Si—H bonds on the surface 14 thereof is obtained.

If the dangling bonds 15 exposed onto the surface 14 are end-capped, the surface 14 of the first silicon base member 1 becomes chemically stable. Therefore, even if the first silicon base member 1 on which the dangling bonds 15 have been end-capped is left in an atmosphere, it is possible to prevent an oxide film from being formed on the surface 14 of the first silicon base member 1.

In other words, it is possible to maintain a state that the Si—H bonds are formed on the surface 14 of the first silicon base member 1 in high density. Therefore, such a state makes it possible to preserve or store the first silicon base member 1 on which the dangling bonds 15 have been end-capped in even the atmosphere if a short period of time (about one hour).

Further, in a case where the first silicon base member 1 having the Si—H bonds on the surface 14 thereof is preserved or stored for a long period of time, it is preferred that an atmosphere to preserve or store the first silicon base member 1 is an inert gas atmosphere such as argon gas atmosphere, or a reduced-pressure atmosphere. Such an atmosphere makes it possible to stably maintain the Si—H bonds on the surface 14 even a long period of time over a few hours.

[1-3] Next, the oxide film 13 is subjected to an etching treatment to expose the Si—H bonds. Then, energy is applied to the surface 14 of the first silicon base member 1 (base material 12).

Examples of such a method of applying the energy to the silicon 14 include a method of irradiating an energy beam, a method of heating the first silicon base member 1, and the like. The method of applying the energy to the silicon 14 makes it possible to apply a predetermined amount of the energy to a predetermined region of the surface 14.

On the other hand, the method of heating the first silicon base member 1 makes it possible to apply the energy to the surface 14 of the first silicon base member 1 with ease without the use of expensive equipment. Hereinafter, a description will be made on each method one after another.

Examples of the energy beam include: a light such as an ultraviolet light and a laser light; an electron beam; a particle beam; and the like. Among these energy beams mentioned above, it is particularly preferred that the energy beams to be used are the ultraviolet light or the laser light (see FIG. 1D).

The use of such a laser light makes it possible to selectively and efficiency cut the Si—H bonds while preventing the first silicon base member 1 from being altered and deteriorated. Further, the use of such an ultraviolet light also makes it possible to selectively and efficiency cut the Si—H bonds over a large area (region) of the first silicon base member 1 with relatively simple equipment such as an ultraviolet lump.

Examples of the laser light include: a pulse oscillation laser (a pulse laser) such as an excimer laser; a continuous oscillation laser such as a carbon dioxide laser or a semiconductor laser; and the like. Among these lasers, it is preferred that the pulse laser is used in this embodiment.

Use of the pulse laser makes it difficult to accumulate heat in a portion of the first silicon base member 1 where the laser light is irradiated with time. Therefore, it is possible to reliably prevent alteration and deterioration of the first silicon base member 1 due to the heat accumulated. In other words, it is possible to prevent heat accumulated inside the first silicon base member 1 from having an adverse affect on the first silicon base member 1.

In the case where influence of the heat is taken into account, it is preferred that a pulse width of the pulse laser is as small as possible. Specifically, the pulse width is preferably equal to or smaller than 1 ps (picosecond), and more preferably equal to or smaller than 500 fs (femtoseconds).

By setting the pulse width to the above range, it is possible to reliably suppress the influence of the heat generated in the first silicon base member 1 due to the irradiation with the laser light. In this regard, it is to be noted that the pulse laser having the small pulse width of the above range is called as “femtosecond laser”.

A wavelength of the laser light is not particularly limited to a specific value, but is preferably in the range of about 200 to 1200 nm, and more preferably in the range of about 400 to 1000 nm. Further, in case of the pulse laser, peak power of the laser light is preferably in the range of about 0.1 to 10 W, and more preferably in the range of about 1 to 5 W, although being different depending on the pulse width thereof.

Moreover, a repetitive frequency of the pulse laser is preferably in the range of about 0.1 to 100 kHz, and more preferably in the range of about 1 to 10 kHz. By setting the frequency of the pulse laser to the above range, a temperature of a portion where the laser light is irradiated extremely rises and the Si—H bonds can be reliably cut while preventing the Si—Si bonds from being cut.

Various conditions for such a laser light are appropriately set so that the temperature in the portion where the laser light is irradiated is preferably in the range of about room temperature to 600° C., more preferably 200 to 600° C., and even more preferably in the range of 300 to 400° C. This temperature makes it possible to selectively cut only the Si—H bonds at the portion where the laser light is irradiated without cutting most of Si—Si bonds.

Particularly, in a case where the first silicon base member 1 is constituted of amorphous silicon, a temperature of the irradiated portion becomes too high, and therefore it is possible to reliably prevent amorphous silicon from being crystallized.

The laser light irradiated on the first silicon base member 1 is preferably scanned along the surface 14 of the first silicon base member 1 with a focus thereof set on the surface 14 thereof. By doing so, heat generated by the irradiation of the laser light is locally accumulated at the vicinity of the surface 14 of the first silicon base member 1. As a result, it is possible to selectively cut the Si—H bonds existing the surface 14 of the first silicon base member 1.

In a case where the ultraviolet light is used as the irradiated energy beam, a wavelength of the ultraviolet light is preferably in the range of about 150 to 300 nm, and more preferably in the range of about 160 to 200 nm. Further, a time for irradiating the ultraviolet light is not limited to a specific value, but is preferably in the range of about 0.5 to 30 minutes and more preferably in the range of about 1 to 10 minutes.

On the other hand, in a case where the first silicon base member 1 is heated, a heating temperature of the first silicon base member 1 is in the range of about 200 to 600° C., and more preferably in the range of about 300 to 400° C. Since bonding energy of the Si—H bonds is smaller than that of the Si—Si bonds, it is possible to selectively cut the Si—H bonds by setting the heating temperature of the first silicon base member 1 to fall within the above range.

When the Si—H bonds of the surface 14 are cut, the dangling bonds 15 of silicon are exposed on the surface 14 of the first silicon base member 1 as shown in FIG. 2E.

According to the present invention, the energy is applied to the surface 14 of the first silicon base member 1 on which the Si—H bonds exist and which maintains a chemically stable state. By doing so, the dangling bonds 15 of silicon are exposed on the surface 14 for a very short period of time, thereby activating the surface 14. Therefore, if this step is performed just before the performance of the bonding step as described later, it is possible to suppress production of an oxide film and pollution of the surface 14.

In this embodiment, the description has been made on the method which includes the step of subjecting the surface of the base member 11 constituted of silicon material to the etching treatment using the hydrofluoric acid-containing liquid 20 to obtain the first silicon base member 1 having the Si—H bonds on the surface 14. However, the method (step) of obtaining the first silicon base member 1 having the Si—H bonds on the surface 14 is not limited to the method as described above, but may be other methods (steps).

[2] Bonding Step (Second Step)

In this embodiment, the second step includes the follow two steps.

[2-1] A providing step is a step of obtaining a second silicon base member 2 that dangling bonds 25 are exposed on a surface 24 thereof as the step [1] described above. [2-2] An overlapping step is a step of overlapping the first silicon base member 1 and the second silicon base member 2 to be in contact the surface 14 of the first silicon base member 1 with the surface 24 of the second silicon base member 2. Hereinafter, a description will be made on this step one after another.

[2-1] First, a base member is provided (not shown in drawings). The base member is constituted of amorphous silicon, crystalline silicon, or the like which is the same as that of the base member 11 of the step [1].

Next, the base member is subjected to an etching treatment which is the same as that of the step [1] described above. Thereafter, energy is applied to the etching-treated surface of the base member. Consequently, the second silicon base member 2, that the dangling bonds 25 are exposed on the surface 24 thereof, is obtained as shown in FIG. 2F.

In the etching process (step) to be performed to the base member, a hydrofluoric acid-containing liquid can preferably be used for the etching process. Such a hydrofluoric acid-containing liquid makes it possible to reliably remove a oxide film formed on the surface of the base member. In this regard, it is to be noted that the hydrofluoric acid-containing liquid can be used the same one as that of step [1] described above.

When the oxide film is removed from the surface of the base member, dangling bonds of silicon are exposed thereon. However, hydrogen ions contained in the hydrofluoric acid-containing liquid are quickly bonded to the dangling bonds of silicon, thereby end-capping the dangling bonds. In this way, the second silicon base member 2 having the Si—H bonds on the surface 24 thereof is obtained.

If the energy is applied to the surface 24 of the second silicon base member 2 (base member), the Si—H bonds are selectively cut, so that the dangling bonds 25 on the surface 24 thereof are exposed.

In this embodiment, the description has been made on the method which includes the step of subjecting the surface of the base member constituted of silicon material to the etching treatment using the hydrofluoric acid-containing liquid and then the step of applying the energy to the etching-treated surface to selectively cut the Si—H bonds to obtain the second silicon base member 2 having the dangling bonds 25 of silicon on the surface 24. However, the method (step) of obtaining the second silicon base member 2 having the dangling bonds 25 of silicon on the surface 24 is not limited to the method as described above, but may be other methods (steps).

[2-2] Next, the first silicon base member 1 and the second silicon base member 2 are overlapped to each other so as to be in contact the surface 14 of the first silicon base member 1 which have been obtained in the step [1] with the surface 24 of the second silicon base member 2 provided in the step [2-1] as shown in FIG. 2F.

By performing the step, the dangling bonds 15 of silicon exposed on the surface 14 of the first silicon base member 1 are bonded to the dangling bonds 25 of silicon exposed on the surface 24 of the second silicon base member 2 to form Si—Si bonds. As a result, the first silicon base member 1 is bonded to the second silicon base member 2 to obtain a bonded body 3 as shown in FIG. 2G. In the thus obtained bonded body, the first silicon base member 1 and the second silicon base member 2 are bonded together with high bonding strength and high accuracy.

In a state that the first silicon base member 1 and the second silicon base member 2 are overlapped to each other as described above, if necessary, they are heated. This makes is possible to shorten the amount of time needed to the bonding process and increase bonding strength of the bonded body 3.

A heating temperature during the heating process is preferably in the range of about 40 to 200° C., and more preferably in the range of about 50 to 150° C. This makes is possible to sufficiently shorten the amount of time needed to the bonding process and increase bonding strength of the bonded body 3. In addition, it is possible to prevent the first silicon base member 1 and the second silicon base member 2 from being altered and deteriorated due to the heat.

In a state that the first silicon base member 1 and the second silicon base member 2 are overlapped to each other as described above, if necessary, they are pressed in a direction of approaching them to each other. This makes it possible to increase bonding strength of the bonded body 3.

At this time, a pressure of pressing the bonded body 3 is preferably in the range of about 1 to 1000 MPa, and more preferably in the range of about 1 to 10 MPa, although being slightly different depending on the constituent materials and thicknesses of the first silicon base member 1 and the second silicon base member 2, and the like.

If the pressure of pressing the bonded body 3 falls within the above range, it is possible to reliably increase bonding strength of the bonded body 3, while preventing the first silicon base member 1 and the second silicon base member 2 from being damaged.

In this regard, it is to be noted that the heating process and the pressing process are preferably performed simultaneously. By doing so, an effect by pressing and an effect by heating are exhibited synergistically. Therefore, it is possible to increase bonding strength of the bonded body 3.

It is preferred that the steps [1] and [2] as described above are performed in an inert gas (e.g. nitrogen gas and argon gas) atmosphere or a reduced-pressure atmosphere. This makes it possible to reliably prevent the surface 14 of the first silicon base member 1 and the surface 24 of the second silicon base member 2 from being polluted and oxidized by adhesion of oxygen and moisture contained in an atmosphere. As a result, it is possible to prevent the dangling bonds 15 exposed on the surface 14 and the dangling bonds 25 exposed on the surface 24 from being undesirably end-capped (inactivated) by oxygen and moisture.

In this regard, it is to be note that a state that the dangling bonds 15 of silicon are exposed on the surface 14 of the first silicon base member 1, that is an activation state, are reduced (changed) over time. Therefore, after the dangling bonds 15 of silicon are exposed on the surface 14 of the first silicon base member 1 in the step [1-3], the step [2-2] is performed as soon as possible.

Likewise, after the dangling bonds 25 of silicon are exposed on the surface 24 of the second silicon base member 2 in the step [2-1], this step [2-2] is performed as soon as possible.

Specifically, after the steps [1-3] and [2-1] are completed, this step [2-2] is preferably performed within 5 minutes, and more preferably within 3 minutes. The performance of the step [2-2] within such a time makes it possible to obtain sufficient bonding strength when the first silicon base member 1 and the second silicon base member 2 are bonded to each other in this step [2-2]. This is because a sufficient active state is maintained in the surface 14 and the surface 15.

In the bonding method of the silicon base members as described above, it is possible to bond the surface 24 of the second silicon base member 2 to the surface 14 of the first silicon base member 1 with sufficient bonding strength without the heating process at a high temperature. Therefore, it is possible to prevent the second silicon base member 2 and the first silicon base member 1 from being altered and deteriorated due to the heat.

Furthermore, according to the present invention, when the surface 14 of the first silicon base member 1 and the surface 24 of the second silicon base member 2 are bonded to each other, the surface 14 and the surface 24 are bonded together by Si—Si bonds. Therefore, it is possible to firmly bond the first silicon base member 1 and the second silicon base member 2 together as compared with a case that bonding surfaces are bonded to each other by Si—O—Si bonds as a conventional bonded body.

Furthermore, according to the present invention, it is possible to obtain a bonded body 3 having uniform characteristics (mechanical characteristics, electric characteristics, and chemical characteristics).

Furthermore, it is possible to bond the first silicon base member 1 and the second silicon base member 2 together with high bonding strength and high accuracy. Furthermore, according to the present invention, it is possible to obtain a bonded body 3 regardless of crystal structures and compositions of the first silicon base member 1 and the second silicon base member 2.

The bonded body 3 of the silicon base members obtained by using the bonding method of the silicon base members as described above can be used for some applications. Examples of such applications include semiconductor elements, MEMS, various kinds of packages and the like.

Hereinafter, a description will be made on a case where the bonded body obtained by using the bonding method of the silicon base members according to the present invention is used for a diode (semiconductor element).

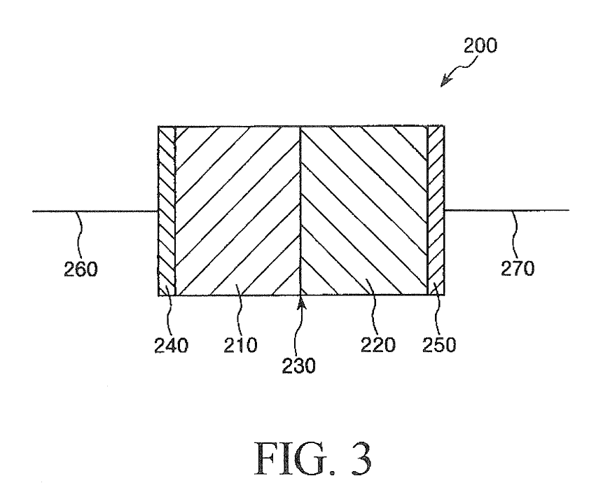

FIG. 3 is a vertical sectional view showing a diode produced by using the bonding method of the silicon base members according to the present invention. In the following description, the left side in FIG. 3 will be referred to as “left” and the right side thereof will be referred to as “right” for convenience of explanation.

A diode 200 shown in FIG. 3 has a p-type silicon base member 210 and an n-type silicon base member 220 which are bonded together at a bonding surface 230.

An anode 240 is provided to a left surface of the p-type silicon base member 210, and a cathode 250 is provided to a right surface of the n-type silicon base member 220. Furthermore, a lead 260 is connected with the anode 240 and a lead 270 is connected with the anode 250.

Here, the p-type silicon base member 210 is constituted of a material in which a low amount of a p-type dopant of a trivalent element such as boron (B), indium (In), and the like is added to a silicon material of amorphous silicon containing hydrogen, a crystal silicon containing hydrogen, or the like.

On the other hand, the n-type silicon base member 220 is constituted of a material in which a low amount of a n-type dopant of a pentavalent element such as phosphorous (P), arsenic (As), antimony (Sb), and the like is added to the same silicon material as that of the p-type silicon base member 210.

Such a p-type silicon base member 210 and n-type silicon base member 220 is bonded to each other by using the bonding method according to the present invention. In this way, the p-type silicon base member 210 and the n-type silicon base member 220 are bonded together in a state of very low contact resistance.

As a result, the p-type silicon base member 210 and the n-type silicon base member 220 are bonded together with a pn bonding, so that the diode 200 exhibits commutating action. The diode 200 obtained by using the bonding method according to the present invention has high reliability.

Ink Jet Type Recording Head

Now, a description will be made on an embodiment of a droplet ejection head in which the bonded body produced by using the bonding method of the silicon base members according to the present invention is used.

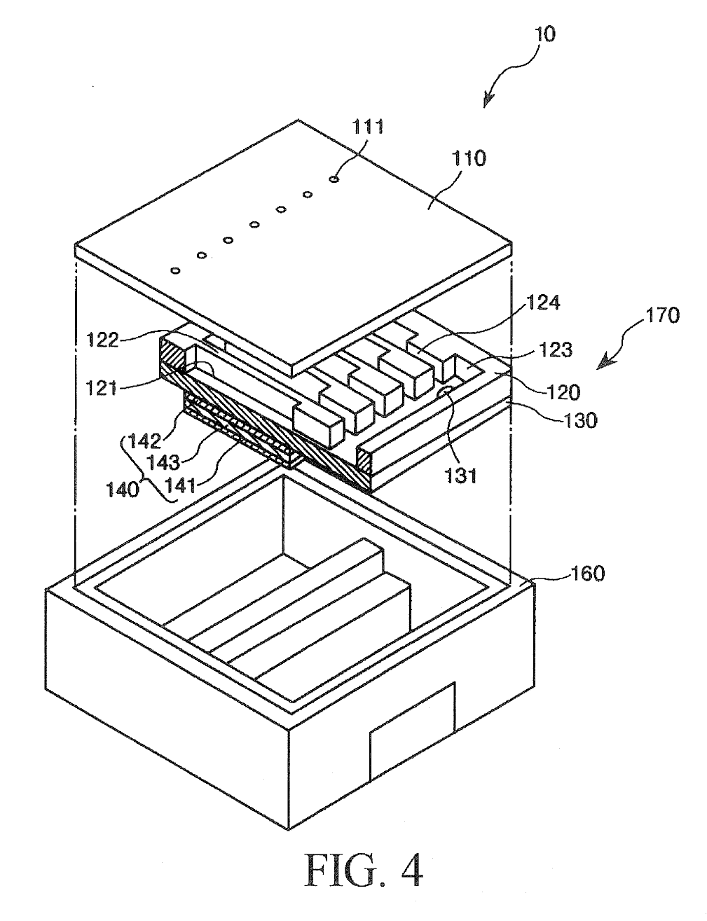

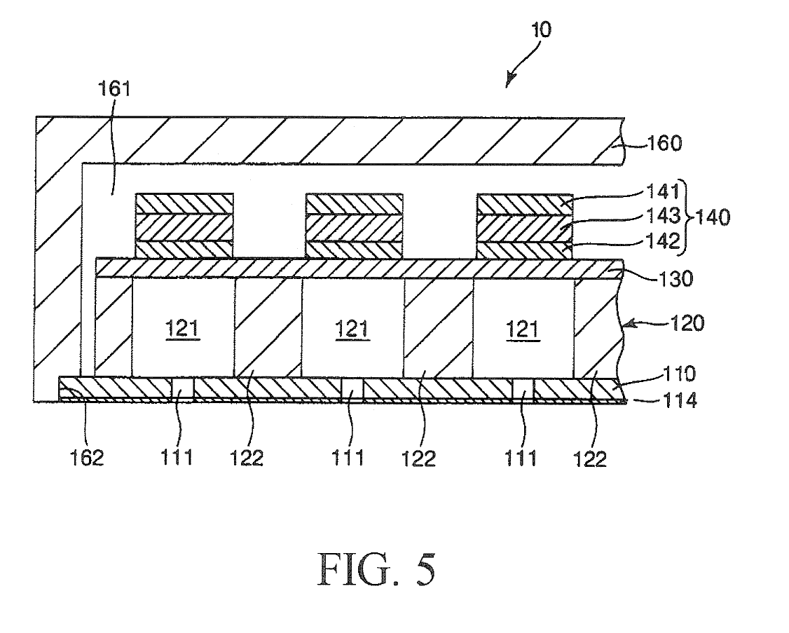

FIG. 4 is an exploded perspective view showing an ink jet type recording head (a droplet ejection head) in which the bonded body according to the present invention is used. FIG. 5 is a section view illustrating major parts of the ink jet type recording head shown in FIG. 4.

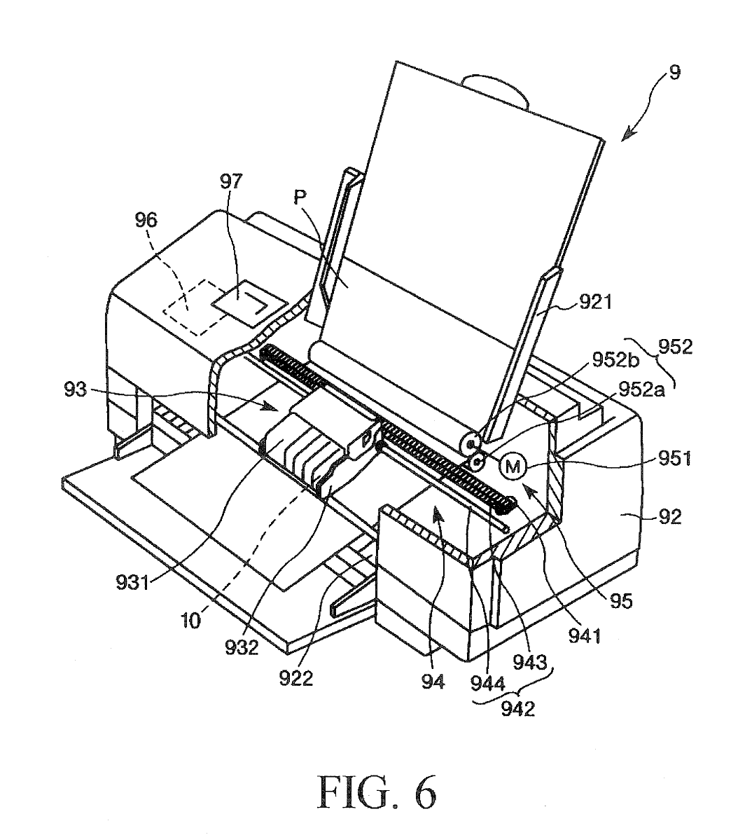

FIG. 6 is a schematic view showing one embodiment of an ink jet printer equipped with the ink jet type recording head shown in FIG. 4. In FIG. 4, the ink jet type recording head is shown in an inverted state as distinguished from a typical use state.

The ink jet type recording head (droplet ejection head according to the present invention) 10 shown in FIG. 4 is mounted to the ink jet printer (droplet ejection apparatus according to the present invention) 9 shown in FIG. 6.

The ink jet printer 9 shown in FIG. 6 includes a printer body 92, a tray 921 provided in the upper rear portion of the printer body 92 for holding recording paper sheets P, a paper discharging port 922 provided in the lower front portion of the printer body 92 for discharging the recording paper sheets P therethrough, and an operation panel 97 provided on the upper surface of the printer body 92.

The operation panel 97 is formed from, e.g., a liquid crystal display, an organic EL display, an LED lamp or the like. The operation panel 97 includes a display portion (not shown) for displaying an error message and the like and an operation portion (not shown) formed from various kinds of switches.

Within the printer body 92, there are provided a printing device (a printing means) 94 having a reciprocating head unit 93, a paper sheet feeding device (a paper sheet feeding means) 95 for feeding the recording paper sheets P into the printing device 94 one by one and a control unit (a control means) 96 for controlling the printing device 94 and the paper sheet feeding device 95.

Under the control of the control unit 96, the paper sheet feeding device 95 feeds the recording paper sheets P one by one in an intermittent manner. The recording paper sheet P passes near the lower portion of the head unit 93. At this time, the head unit 93 makes reciprocating movement in a direction generally perpendicular to the feeding direction of the recording paper sheet P, thereby printing the recording paper sheet P.

In other words, an ink jet type printing operation is performed, during which time the reciprocating movement of the head unit 93 and the intermittent feeding of the recording paper sheets P act as primary scanning and secondary scanning, respectively.

The printing device 94 includes a head unit 93, a carriage motor 941 serving as a driving power source of the head unit 93 and a rotated by the carriage motor 941 for reciprocating the head unit 93.

The head unit 93 includes an ink jet type recording head 10 (hereinafter, simply referred to as “a head 10”) having a plurality of formed in the lower portion thereof, an ink cartridge 931 for supplying ink to the head 10 and a carriage 932 carrying the head 10 and the ink cartridge 931.

Full color printing becomes available by using, as the ink cartridge 931, a cartridge of the type filled with ink of four colors, i.e., yellow, cyan, magenta and black.

The reciprocating mechanism 942 includes a carriage guide shaft 943 whose opposite ends are supported on a frame (not shown) and a timing belt 944 extending parallel to the carriage guide shaft 943.

The carriage 932 is reciprocatingly supported by the carriage guide shaft 943 and fixedly secured to a portion of the timing belt 944.

If the timing belt 944 wound around a pulley is caused to run in forward and reverse directions by operating the carriage motor 941, the head unit 93 makes reciprocating movement along the carriage guide shaft 943. During this reciprocating movement, an appropriate amount of ink is ejected from the head 10 to print the recording paper sheets P.

The paper sheet feeding device 95 includes a paper sheet feeding motor 951 serving as a driving power source thereof and a pair of paper sheet feeding rollers 952 rotated by means of the paper sheet feeding motor 951.

The paper sheet feeding rollers 952 include a driven roller 952a and a driving roller 952b, both of which face toward each other in a vertical direction, with a paper sheet feeding path (the recording paper sheet P) remained therebetween. The driving roller 952b is connected to the paper sheet feeding motor 951.

Thus, the paper sheet feeding rollers 952 are able to feed the plurality of recording paper sheets P, which are held in the tray 921, toward the printing device 94 one by one. In place of the tray 921, it may be possible to employ a construction that can removably hold a paper sheet feeding cassette containing the recording paper sheets P.

The control unit 96 is designed to perform printing by controlling the printing device 94 and the paper sheet feeding device 95 based on the printing data inputted from a host computer, e.g., a personal computer or a digital camera.

Although not shown in the drawings, the control unit 96 is mainly comprised of a memory that stores a control program for controlling the respective parts and the like, a piezoelectric element driving circuit for driving piezoelectric elements (vibration sources) 14 to control an ink ejection timing, a driving circuit for driving the printing device 94 (the carriage motor 941), a driving circuit for driving the paper sheet feeding device 95 (the paper sheet feeding motor 951), a communication circuit for receiving printing data from a host computer, and a CPU electrically connected to the memory and the circuits for performing various kinds of control with respect to the respective parts.

Electrically connected to the CPU are a variety of sensors capable of detecting, e.g., the remaining amount of ink in the ink cartridge 931 and the position of the head unit 93.

The control unit 96 receives printing data through the communication circuit and then stores them in the memory. The CPU processes these printing data and outputs driving signals to the respective driving circuits, based on the data thus processed and the data inputted from the variety of sensors. Responsive to these signals, the piezoelectric elements 14, the printing device 94 and the paper sheet feeding device 95 come into operation, thereby printing the recording paper sheets P.

Hereinafter, the head (droplet ejection head according to the present invention) 10 will be described in detail with reference to FIGS. 4 and 5.

The head 10 includes a head main body 170 and a base body (casing) housing the head main body 170. The head main body 170 includes a nozzle plate (first base member) 110 in which a plurality of nozzle holes 111 are formed, an ink chamber base plate (second base member) 120 provided with a reservoir (liquid reservoir space) 121 for temporarily reserving an ink (liquid) and disposed so as to correspond to the nozzle holes 111.

Furthermore, the head main body 170 includes a vibration plate 130 for changing a volume of the reservoir 121, and a plurality of piezoelectric elements (vibration sources) 140 bonded to the vibration plate 130. The head 10 constitutes a piezo jet type head of on-demand style.

The nozzle plate 110 is made of, e.g., a silicon-based material such as SiO₂, SiN or quartz glass, a metallic material such as Al, Fe, Ni, Cu or alloy containing these metals, an oxide-based material such as alumina or ferric oxide, a carbon-based material such as carbon black or graphite, and the like.

A plurality of nozzle holes 111 for ejecting ink droplets therethrough is formed in the nozzle plate 110. The pitch of the nozzle holes 111 is suitably set according to the degree of printing accuracy.

The ink chamber base plate 120 is fixed or secured to the nozzle plate 110. In the ink chamber base plate 120, there are formed a plurality of ink chambers (cavities or pressure chambers) 121, a reservoir chamber 123 for reserving ink supplied from the ink cartridge 931 and a plurality of supply ports 124 through which ink is supplied from the reservoir chamber 123 to the respective ink chambers 121. These chambers 121, 123 and 124 are defined by the nozzle plate 110, the side walls (barrier walls) 122 and the below mentioned vibration plate 130.

The respective ink chambers 121 are formed into a reed shape (a rectangular shape) and are arranged in a corresponding relationship with the respective nozzle holes 111. Volume of each of the ink chambers 121 can be changed in response to vibration of the vibration plate 130 as described below. Ink is ejected from the ink chambers 121 by virtue of this volume change.

In this embodiment, the ink chamber base plate 120 is constituted from a silicon substrate. The nozzle plate 110 and the ink chamber base plate 120 are bonded to each other by using the bonding method of the silicon base members according to the present invention. In this way, the nozzle plate 110 and the ink chamber base plate 120 are bonded together with high strength and high accuracy. As a result, it is possible to suppress variations of volumes of the respective ink chambers 121, the reservoir chamber 123, and the plurality of supply ports 124. This makes it possible to uniformly eject the inks from the nozzle holes 111.

The vibration plate 130 is bonded to the opposite side of the ink chamber base plate 120 from the nozzle plate 110. The plurality of piezoelectric elements 140 are provided on the opposite side of the vibration plate 130 from the ink chamber base plate 120.

In a predetermined position of the vibration plate 130, a communication hole 131 is formed through a thickness of the vibration plate 130. Ink can be supplied from the ink cartridge 931 to the reservoir chamber 123 through the communication hole 131.

Each of the piezoelectric elements 140 includes an upper electrode 141, a lower electrode 142 and a piezoelectric body layer 143 interposed between the upper electrode 141 and the lower electrode 142. The piezoelectric elements 140 are arranged in alignment with the generally central portions of the respective ink chambers 121.

The piezoelectric elements 140 are electrically connected to the piezoelectric element driving circuit and are designed to be operated (vibrated or deformed) in response to the signals supplied from the piezoelectric element driving circuit.

The piezoelectric elements 140 act as vibration sources. The vibration plate 130 is vibrated by operation of the piezoelectric elements 140 and has a function of instantaneously increasing internal pressures of the ink chambers 121.

In this embodiment, a droplet ejection means is composed from the vibration plate 130 and the piezoelectric elements 140. The droplet ejection means ejects the inks reserved in the ink chambers 121 from the nozzle holes 111 as droplets.

The base body 160 has a recess portion 161 that can receive the head main body 170. In a state that the head main body 17 is received in a recess portion 161 of the base body 160, an edge of the nozzle plate 110 is supported on a shoulder 162 of the base body 160 extending along an outer circumference of the recess portion 161.

With the head 10 set forth above, no deformation occurs in the piezoelectric body layer 143, in the case where a predetermined ejection signal has not been inputted from the piezoelectric element driving circuit, that is, a voltage has not been applied between the upper electrode 141 and the lower electrode 142 of each of the piezoelectric elements 140.

For this reason, no deformation occurs in the vibration plate 130 and no change occurs in the volumes of the ink chambers 121. Therefore, the ink droplets have not been ejected from the nozzle holes 111.

On the other hand, the piezoelectric body layer 143 is deformed, in the case where the predetermined ejection signal is inputted from the piezoelectric element driving circuit, that is, the voltage is applied between the upper electrode 141 and the lower electrode 142 of each of the piezoelectric elements 140.

Thus, the vibration plate 130 is heavily deflected to change the volumes of the ink chambers 121. At this moment, pressures within the ink chambers 121 are instantaneously increased and the ink droplets are ejected from the nozzle holes 111.

When one ink ejection operation has ended, the piezoelectric element driving circuit ceases to apply the voltage between the upper electrode 141 and the lower electrode 142. Thus, the piezoelectric elements 140 are returned substantially to their original shapes, thereby increasing the volumes of the ink chambers 121.

At this time, a pressure acting from the ink cartridge 931 toward the nozzle holes 111 (a positive pressure) is imparted to the ink. This prevents an air from entering the ink chambers 121 through the nozzle holes 111, which ensures that the ink is supplied from the ink cartridge 931 (the reservoir chamber 123) to the ink chambers 121 in a quantity corresponding to the quantity of the ink ejected.

By sequentially inputting ejection signals from the piezoelectric element driving circuit to the piezoelectric elements 140 lying in target printing positions, it is possible to print an arbitrary (desired) letter, figure or the like.

The head 10 may be provided with thermoelectric conversion elements in place of the piezoelectric elements 140. In other words, the head 10 may have a configuration in which the ink is ejected using a thermal expansion of a material caused by the thermoelectric conversion elements (which is sometimes called a bubble jet method wherein the term “bubble jet” is a registered trademark).

In the head 10 configured as above, a film 114 is formed on the nozzle plate 110 in an effort to impart liquid repellency thereto. By doing so, it is possible to reliably prevent the ink droplets from adhering to peripheries of the nozzle holes 111, which would otherwise occur when the ink droplets are ejected from the nozzle holes 111.

As a result, it becomes possible to make sure that the ink droplets ejected from the nozzle holes 111 are reliably landed (hit) on target regions.

Electronic Device

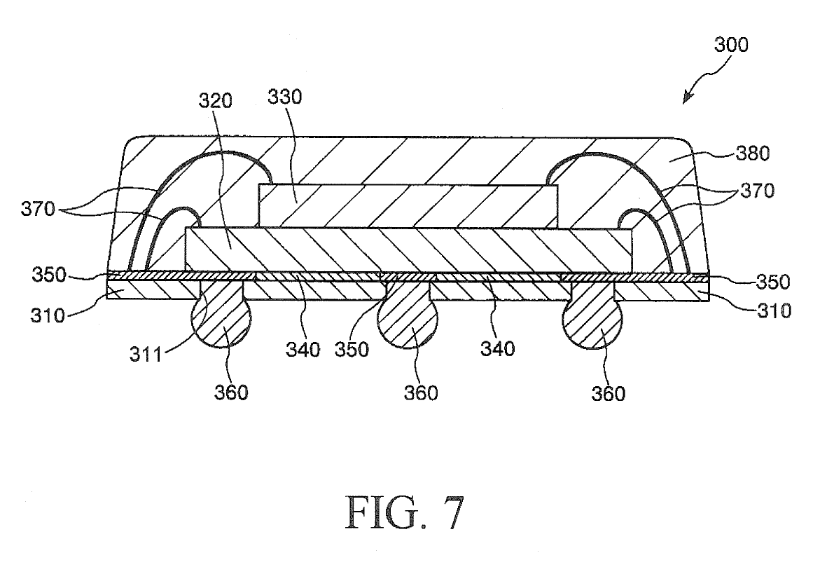

Now, a description will be made on an embodiment of an electronic device in which the bonded body of the silicon base members produced by using the bonding method of the silicon base members according to the present invention is used. FIG. 7 is a vertical sectional view showing an electronic device produced by using the bonding method of the silicon base members according to the present invention. In the following description, the upper side in FIG. 7 will be referred to as “upper” and the lower side thereof will be referred to as “lower” for convenience of explanation.

An electronic device (an electronic device according to the present invention) 300 shown in FIG. 7 includes an insulating substrate 310, a silicon tip 320 mounted on the insulating substrate 310 through a insulating layer 340 and a conductive layer 350, and a silicon tip 330 mounted on the silicon tip 320.

The insulating layer 340 and the conductive layer 350 are provided between the insulating substrate 310 and the silicon tip 320. The conductive layer 350 is bonded to solder balls 360 inserted in through holes 311 which are formed through the insulating substrate 310. In this way, the conductive layer 350 is conducted with the solder balls 360.

In this regard, a circuit (not shown) is formed in the two silicon tips 320 and 330, respectively. The circuit is formed by using a general semiconductor manufacture process.

One ends of wires 370 are connected with the circuits formed in the silicon tips 320 and 330, respectively. On the other hand, the other ends of the wires 370 are connected with the conductive layer 350 formed on the insulating substrate 310. In this way, the circuit formed in each of the two silicon tips 320 and 330 is electrically connected with the solder balls 360.

Furthermore, a sealing portion 380 is provided on the insulating substrate 310. The sealing portion 380 insulates and seals the two silicon tips 320 and 330, and the wires 370 by covering them.

In such an electronic device 300, the two silicon tips 320 and 330 are bonded to each other by using the bonding method of the silicon base members according to the present invention. Specifically, one of the two silicon tips 320 and 330 corresponds to the first silicon base member described above, and the other thereof corresponds to the second silicon base member described above. Therefore, it is possible to firmly bond the two silicon tips 320 and 330 together and improve position accuracy thereof. As a result, the electronic device 300 exhibits high reliability.

By laminating the two silicon tips 320 and 330, it is possible to easily package three-dimensionally. This makes it possible to reduce a planner size of the electronic device 300. If the planner size of the electronic device 300 is the same as those of others electronic devices, it is possible to easily improve components per chip of the electronic device 300.

Although the bonding method of the silicon base members, the droplet ejection head, the droplet ejection apparatus, and the electronic device according to the present invention has been described above based on the embodiments illustrated in the drawings, the present invention is not limited thereto.

If necessary, one or more arbitrary step may be added in the bonding method of the silicon base members according to the present invention. Furthermore, three or more silicon base members may be bonded to each other.

### INDUSTRIAL APPLICABILITY

A bonding method of silicon base members according to the present invention comprises: providing a first silicon base member having a surface and Si—H bonds on the surface; and applying an energy to the surface of the first silicon base member to selectively cut the Si—H bonds so that dangling bonds of the silicon (Si) is exposed on the surface of the first silicon base member.

The bonding method of the silicon base members according to the present invention further comprises: providing a second silicon base member having a surface on which dangling bonds of silicon are exposed; and bonding the surface of the first silicon base member, on which the dangling bonds of the silicon has been exposed, and the surface of the second silicon base member to thereby bond the surface of the first silicon base member and the surface of the second silicon base member together through their dangling bonds.

Therefore, it is possible to accurately and firmly bond the silicon base members together without performance of a heat treatment at a high temperature.

Furthermore, the first silicon base member is bonded to the second silicon base member with Si—Si bonds at a bonding interface therebetween. Therefore, they are firmly bonded to each other as compared with bonding with Si—O—Si bonds as a conventional bonding method. Consequently, uniform mechanical characteristics, uniform electrical characteristics, and uniform chemical characteristics are obtained between the first silicon base member and the second silicon base member. Accordingly, the bonding method of the silicon base members according to the present invention has industrial applicability.

What is claimed is:

1. A bonding method of silicon base members, the bonding method comprising:
applying an energy to a surface of a first silicon base member having Si—H bonds on the surface to selectively cut the Si—H bonds so that dangling bonds of the silicon (Si) is exposed on the surface of the first silicon base member; and
bonding the surface of the first silicon base member, on which the dangling bonds of the silicon has been exposed, and a surface of a second silicon base member on which dangling bonds of silicon are exposed so that the surface of the first silicon base member and the surface of the second silicon base member are bonded together through their dangling bonds.

2. The bonding method of the silicon base members as claimed in claim 1, wherein the energy includes a laser light, and the applying the energy to the surface of the first silicon base member is performed by irradiating the laser light.

3. The bonding method of the silicon base members as claimed in claim 2, wherein the laser light includes a pulse laser.

4. The bonding method of the silicon base members as claimed in claim 1, wherein the first silicon base member has a part in which the laser light has been irradiated, and conditions of irradiating the laser light to the surface of the first silicon base member are adjusted so that a temperature of the part is in the range of room temperature to 600° C.

5. The bonding method of the silicon base members as claimed in claim 1, wherein the applying the energy to surface of the first silicon base member is performed with heating the first silicon base member.

6. The bonding method of the silicon base members as claimed in claim 5, wherein a temperature of heating the first silicon base member is in the range of 200 to 600° C.

7. The bonding method of the silicon base members as claimed in claim 1, wherein the first silicon base member is provided by:
providing a base member constituted of a silicon material, the base member having a surface; and
subjecting the surface of the base member to an etching treatment using a hydrofluoric acid-containing liquid to provide the first silicon base member.

8. The bonding method of the silicon base members as claimed in claim 7, wherein the base member constituted of the silicon material is formed by a CVD method using a silane-based gas as a raw gas.

9. The bonding method of the silicon base members as claimed in claim 1, wherein the applying the energy to the surface of the first silicon base member and the
bonding the surface of the first silicon base member and the surface of the second silicon base member are performed in an inert gas atmosphere or a reduced-pressure atmosphere.

10. The bonding method of the silicon base members as claimed in claim 1, wherein the bonding the surface of the first silicon base member and the surface of the second silicon base member is performed with heating the first silicon base member and the second silicon base member.

11. The bonding method of the silicon base members as claimed in claim 10, wherein a temperature of heating the first silicon base member and the second silicon base member is in the range of 40 to 200° C.

12. The bonding method of the silicon base members as claimed in claim 1, wherein the bonding the surface of the first silicon base member and the surface of the second silicon base member is performed with pressing the first silicon base member and the second silicon base member in a direction of approaching them to each other.

13. The bonding method of the silicon base members as claimed in claim 12, wherein a pressure of pressing the first silicon base member and the second silicon base member is in the range of 1 to 1000 MPa.

14. The bonding method of the silicon base members as claimed in claim 1, wherein the second silicon base member having the surface on which the dangling bonds of the silicon are exposed is provided by:
providing a base member constituted of a silicon material, the base member having a surface;
subjecting the surface of the base member to an etching treatment using a hydrofluoric acid-containing liquid to form Si—H bonds on the surface of the base member; and
applying an energy to the etching-treated surface of the base member to selectively cut the Si—H bonds so that the dangling bonds of the silicon are exposed on the surface of the base member corresponding to the second silicon base member.

15. A droplet ejection head provided with a bonded body manufactured by bonding two silicon base members together, wherein the bonded body is manufactured by the bonding method of the silicon base members defined in claim 1.

16. A droplet ejection apparatus provided with the droplet ejection head defined in claim 15.

17. An electronic device provided with a bonded body manufactured by bonding two silicon base members together, wherein the bonded body is manufactured by the bonding method of the silicon base members defined in claim 1.
